(19) United States
(12) Patent Application Publication
(10) Pub. No.: US 2017/0025254 A1
(43) Pub. Date: Jan. 26, 2017

(54) PLASMA PROCESSING APPARATUS

(71) Applicant: Hitachi High-Technologies Corporation, Tokyo (JP)

(72) Inventors: Takumi TANDOU, Tokyo (JP); Takamasa ICHINO, Tokyo (JP); Kenetsu YOKOGAWA, Tokyo (JP); Yutaka OHMOTO, Tokyo (JP)

(21) Appl. No.: 15/216,148

(22) Filed: Jul. 21, 2016

(30) Foreign Application Priority Data
Jul. 22, 2015 (JP) 2015-144547

(51) Int. Cl. H01J 37/32; C23C 16/50; C23C 14/48

(52) U.S. Cl. CPC H01J 37/32009; C23C 14/48; C23C 16/50; H01J 2237/334; H01J 2237/3321

(57) ABSTRACT

A plasma processing device includes: a processing chamber which is disposed in a vacuum vessel and is compressed; a sample stage which is disposed in the processing chamber and on which a wafer of a process target is disposed and held; and a mechanism for forming plasma in the processing chamber on the sample stage, wherein the sample stage includes a block which is made of a dielectric and has a discoid shape, a jacket which is disposed below the block with a gap therebetween, is made of a metal, and has a discoid shape, a recessed portion which is disposed in a center portion of a top surface of the jacket and into which a cylindrical member disposed below a center portion of the block and made of a dielectric is inserted, and a cooling medium flow channel disposed in the jacket and through which a cooling medium circulates.

### BACKGROUND OF THE INVENTION

1. Field of the Invention

The present invention relates to a plasma processing device that processes a sample of a substrate shape such as a semiconductor wafer disposed on a sample stage disposed in a processing chamber decompressed in a vacuum vessel using plasma formed in the processing chamber and more particularly, to a plasma processing device that adjusts a temperature of a sample stage on which a sample is disposed and processes the sample.

2. Description of the Related Art

In a field of a semiconductor device, it is increasingly demanded to miniaturize a circuit structure to realize higher integration. In manufacturing of the semiconductor device, processing precision required for a process for processing a film structure of a top surface of a semiconductor wafer by dry etching becomes higher. Recently, a nonvolatile material is used increasingly in a semiconductor element. As a representative example, a magnetic random access memory (MRAM) to store data using magnetic resistance is known. As a magnetic material, a nonvolatile material such as CoFeB is used. In a process for etching a film layer of the nonvolatile material, because the material has low chemical reactivity, a sputtering effect by kinetic energy when ions of plasma are caused to collide with the film layer becomes a main etching mechanism.

In etching in which the sputtering effect is high, residual products generated during the etching of the semiconductor wafer are attached to a sidewall of a groove or a hole of a film during the etching and a shape of a longitudinal cross-section of the groove or the hole becomes a tapered shape. If the tapered shape is generated, a wiring width of a circuit deviates greatly from a predetermined wiring width and it becomes difficult to miniaturize the semiconductor device (achieve a mounting density). In addition, the possibility that a failure cause such as a short circuit between elements occurs becomes high and a yield is lowered.

To prevent a processing shape by the etching from becoming the tapered shape, it is known conventionally that it is effective to maintain the temperature of the wafer at the time of the etching high. Generally, an attachment coefficient of the residual products depends on the temperature and the attachment coefficient decreases when the temperature increases. From this, the temperature of the wafer is increased, so that it is possible to increase the probability that the residual products are exhausted without being attached to a lateral surface of the element, and the shape after the processing is suppressed from becoming the tapered shape.

In a typical plasma processing device, to adjust the temperature of the wafer during processing to a value in a desired range, the internal temperature of the sample stage or the temperature of a surface of a dielectric film on the sample stage thermally connected to the sample stage is adjusted while a heat transfer medium such as He gas is supplied between a back surface of the wafer and the dielectric film covering a top surface of the sample stage on which the wafer is disposed. A general configuration of the sample stage includes an electrostatic chuck that has a dielectric film covering a top surface of a base of the metallic sample stage and made of a dielectric such as ceramics like alumina and yttria and an electrode disposed in the dielectric film, generating electrostatic force, and adsorbing and holding the wafer. Heat transfer between the sample stage and the wafer in a vacuum state is accelerated by electrostatically adsorbing the wafer on the top surface of the sample stage and holding the wafer and supplying heat transfer gas between the surface of the dielectric film of the electrostatic chuck and the back surface of the wafer.

In addition, a configuration in which both a cooling mechanism such as a cooling medium flow channel through which a cooling medium circulates and a heating mechanism such as a heater receiving power and generating heat are disposed in the sample stage to adjust the temperature of the sample stage to the value in the desired range is widely known and the temperatures of the sample stage and the wafer disposed on the sample stage and a distribution thereof are adjusted in a predetermined range suitable for processing by adjusting a balance of a heat exhaust amount of the cooling mechanism and a heating amount of the heating mechanism appropriately. Generally, from the magnitude of a heat capacity, in current multiple etching devices, an output of the heater is variably adjusted while the cooling medium of which the temperature is adjusted to a predetermined temperature circulates in the cooling medium flow channel in the sample stage, so that temperatures of a plurality of values used for the processing are realized.

An example of the related art is disclosed in JP-2004-288471-A. JP-2004-288471-A discloses a configuration that includes a cylindrical support member in a center portion of a bottom surface of a flat ceramic susceptor having a resistive heat generation element provided therein and a cooling member disposed in a ring shape to surround the cylindrical support member at an outer circumferential side of the cylindrical support member and having a gap between a back surface of the ceramic susceptor and the cooling member, airtightly seals the gap between the back surface of the ceramic susceptor and the cooling member, supplies heat transfer gas internally to form a heat transfer space, transmits a heat of the ceramic susceptor to the cooling member, and cools the ceramic susceptor. In addition, JP-2004-288471-A discloses a configuration that adjusts an internal pressure of the heat transfer space by an exhaust prevention mechanism to prevent the heat transfer gas from being exhausted from the heat transfer space to which the heat transfer gas is supplied and adjusts a movement amount of the heat through the heat transfer space.

In addition, the transformation of a wafer placement surface can be suppressed by providing a gap between sintered ceramic and the cooling member. For example, in the case in which a cooling medium flow channel is formed in a metallic block, a heater is disposed on the cooling medium flow channel, and an electrostatic chuck is disposed on a top surface of the metallic block, according to a general wafer stage configuration according to the related art, if large power is supplied to the heater to increase the temperature of the wafer, thermal expansion occurs in the vicinity of a heater portion in the metallic block and the entire metallic block is transformed into a convex portion. As a result, the wafer placement surface is also transformed into a convex portion and this causes an electrostatic adsorption error.

Meanwhile, as disclosed in JP-2004-288471-A, the transformation by the thermal expansion does not occur in the sintered ceramic by eliminating restrictions of a radial direction between the sintered ceramic and the cooling member. As a result, the wafer can be electrostatically adsorbed surely at a high temperature.

Further, JP-2015-501546-A discloses a configuration that a high-frequency power supply or a direct-current power supply is electrically connected to an electrostatic chuck including a discoid pack on which a substrate is disposed and which is made of ceramics and a heater disposed in the pack and an internal electrode disposed in the pack. In addition, an outer circumferential end of the internal electrode is disposed to extend to an outer circumferential side more than an outer circumferential edge of the wafer disposed on the electrostatic chuck. As a result, a plasma sheath formed on the electrostatic chuck or the wafer can be prevented from being bent in an outer circumferential end of the wafer during processing, a variation of a processing characteristic with respect to an in-plane direction of the wafer can be reduced, and an etching process can be executed more uniformly.

### SUMMARY OF THE INVENTION

In the related art, a problem occurs because the following points are not sufficiently considered.

That is, in etching of a film layer of a process target configured using a nonvolatile material, it is demanded to increase incidence energy of charged particles such as ions on a film surface to improve verticalization of a processing shape or the throughput. Meanwhile, if the incidence energy of the ions is increased, an amount of heat received by the wafer from the plasma, that is, an amount of heat input from the plasma also increases. For this reason, it is necessary to adjust a value of the temperature of the wafer and a distribution thereof in a desired range sufficient for reducing a variation of a shape after processing as a processing result with respect to an in-plane direction of the wafer, in a state in which the input heat amount is larger than an input heat amount in the past.

Meanwhile, in JP-2004-288471-A, the back surface of the ceramic susceptor of the outer circumferential side of the cylindrical support member is cooled by supplying the heat transfer gas between the cooling member and the ceramic susceptor. However, cooling is not performed actively by the cylindrical support member disposed in the center portion and heat transfer amounts are different in the center portion and the outer circumferential portion. For this reason, when the wafer is processed while a large amount of heat is received, the temperature becomes high in the vicinity of the center of the wafer, a change of the temperature with respect to the radial direction of the wafer increases, a variation of the processing shape increases, and a yield decreases.

Generally, high-frequency power of a predetermined frequency is supplied to the metallic electrode disposed in the sample stage to cause the ions to be incident on the top surface of the wafer and the bias potential is formed on the wafer. However, abnormal discharge may occur in the wafer stage in a state in which the high bias power is supplied to increase the incidence energy of the ions. For example, in the configuration disclosed in JP-2004-288471-A, when a potential difference is generated between the dielectric pack into which the electrode is buried and the cooling member below the pack, the abnormal discharge by the high-frequency power may occur in the gap between the pack and the cooling member and a yield and reliability of the device are lowered.

The above tasks are not considered in JP-2004-288471-A and JP-2015-501546-A and a problem occurs. An object of the present invention is to provide a plasma processing device that has high reliability and an improved yield.

The object is achieved by a plasma processing device including: a processing chamber which is disposed in a vacuum vessel and is compressed; a sample stage which is disposed in the processing chamber and on which a wafer of a process target is disposed and held; and a mechanism for forming plasma in the processing chamber on the sample stage, wherein the sample stage includes a block which is made of a dielectric and has a discoid shape, a jacket which is disposed below the block with a gap therebetween, is made of a metal, and has a discoid shape, a recessed portion which is disposed in a center portion of a top surface of the jacket and into which a cylindrical member disposed below a center portion of the block and made of a dielectric is inserted, and a cooling medium flow channel which is disposed in the jacket and through which a cooling medium circulates; and the block and the jacket transfer heat through a gap between the cylindrical member and a bottom surface of the block of an outer circumferential side thereof.

According to the present invention, a back surface of a dielectric block other than a cylindrical member is cooled by radiation or heat transfer gas between a cooling jacket and the dielectric block and heat is also transferred by the cylindrical member. By this configuration, a temperature of the dielectric block having a heat generation layer can be realized with a desired value or distribution with respect to an in-plane direction thereof. In addition, the heat generation layer and the cooling jacket having diameters larger than an outer diameter of a wafer to be a process target sample are disposed, so that temperature non-uniformity occurring in outer circumferential portions of the heat generation layer and the cooling jacket can be suppressed from affecting in-plane temperature non-uniformity of the process target sample.

Further, a pressure of the heat transfer gas supplied between the dielectric block and the metallic jacket is adjusted, so that a heat transfer amount between the block and the jacket is changed, and a temperature value and a temperature distribution in a desired range with respect to an in-plane direction of the dielectric block can be realized. In addition, an insulator is disposed in a gap between the dielectric block and the metallic jacket and abnormal discharge is suppressed from occurring in the gap between the dielectric block and the metallic jacket.

Therefore, a temperature of the wafer and a distribution with respect to an in-plane direction thereof, which are suitable for processing, can be realized and local heating can be suppressed from occurring by the internal abnormal discharge. As a result, even under a condition of a process for increasing high-frequency power for bias potential formation and increasing an input heat amount, the temperature of the wafer and the distribution thereof can be realized appropriately. In addition, in some embodiments, even in an operation in which the dielectric block and the metallic jacket contact using only the cylindrical member in a center portion and the temperature of the wafer is increased using a heating layer of the block of the upper side, transformation of a top surface of the block on which the wafer is disposed and exfoliation of adsorption of the wafer are suppressed. As a result, it is possible to use the dielectric block in a wide temperature range and it is possible to correspond to a high-temperature region necessary for etching of a nonvolatile material.

### BRIEF DESCRIPTION OF THE DRAWINGS

Other objects and advantages of the invention will become apparent from the following description of embodiments with reference to the accompanying drawings in which:

FIG. 1 is a longitudinal cross-sectional view schematically illustrating a configuration of a plasma processing device according to an embodiment of the present invention;

FIG. 2 is a longitudinal cross-sectional view schematically illustrating a configuration of a sample stage according to the embodiment illustrated in FIG. 1;

FIG. 3 is a longitudinal cross-sectional view schematically illustrating a configuration of a sample stage of a plasma processing device according to a modification of the embodiment illustrated in FIG. 1;

FIG. 4 is a longitudinal cross-sectional view schematically illustrating a configuration of a sample stage of a plasma processing device according to another modification of the embodiment illustrated in FIG. 1;

FIG. 5 is a longitudinal cross-sectional view schematically illustrating a configuration of the sample stage according to the embodiment illustrated in FIG. 2;

FIG. 6 is a graph schematically illustrating a characteristic of discharge in the plasma processing device according to the embodiment illustrated in FIG. 1;

FIG. 7 is a longitudinal cross-sectional view schematically illustrating a configuration of a sample stage of a plasma processing device according to another modification of the embodiment illustrated in FIG. 1; and

FIG. 8 is a longitudinal cross-sectional view schematically illustrating a configuration of a sample stage of a plasma processing device according to another modification of the embodiment illustrated in FIG. 1.

### DESCRIPTION OF THE PREFERRED EMBODIMENTS

Preferred embodiments of the present invention will be described in detail below with reference to the accompanying drawings, wherein like reference numerals refer to like parts throughout.

### First Embodiment

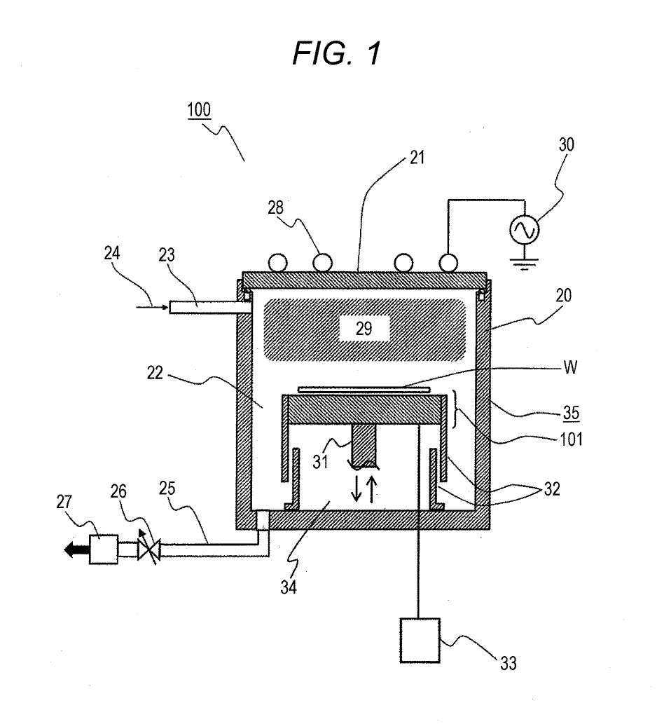

A first embodiment of the present invention will be described hereinafter using FIGS. 1 to 3. FIG. 1 is a longitudinal cross-sectional view schematically illustrating a configuration of a plasma processing device according to an embodiment of the present invention. Particularly, in this embodiment, an etching device that etches a film layer of a process target of a film structure having a plurality of film layers including a mask previously disposed on a surface of a wafer disposed in a processing chamber in a vacuum vessel, using plasma of a so-called induction-coupled type in which the plasma is formed by an induction magnetic field formed by supplying high-frequency power to a coil disposed outside the vacuum vessel, is illustrated.

A plasma processing device 100 according to this embodiment includes a vacuum vessel 35 that internally has a processing chamber 22 decompressed to a predetermined vacuum degree, an electric field formation device that is disposed on the vacuum vessel 35 and forms an electric field to form plasma 29 in the processing chamber 22, and an exhaust device that is disposed below the vacuum vessel and has a vacuum pump including a turbo-molecular pump 27 or a rotary pump for roughing to exhaust the plasma or reaction products in the processing chamber and particles of gas and perform decompression. In the vacuum vessel 35, a sidewall is connected to a conveyance vessel which is a different vacuum vessel not illustrated in the drawings and in which a wafer W is disposed on an arm of a conveyance mechanism such as a conveyance robot and is conveyed in a decompressed state.

The vacuum vessel 35 includes a processing chamber wall 20 of a circular cylindrical shape that surrounds the processing chamber 22 having a circular cylindrical shape and a rid member 21 of a discoid shape that is disposed on an upper end of the processing chamber wall 20 and includes a dielectric, such as alumina ceramic or quartz, transmitting an electric field of a high frequency. A sealing member such as an O-ring not illustrated in the drawings is interposed between the processing chamber wall 20 and the rid member 21 and the processing chamber wall 20 and the rid member 21 are connected by the sealing member, so that an inner side of the processing chamber 22 is airtightly sealed. In addition, a sample stage 101 having a circular cylindrical shape is disposed in a lower portion of the processing chamber 22 and a dielectric placement surface on which the wafer W is disposed is provided on a top surface of the sample stage 101.

A gas introduction pipe 23 is connected to an upper portion of the processing chamber 22 and process gas 24 obtained by mixing one or more kinds of gases stored in a gas source such as a gas tank not illustrated in the drawings with a predetermined ratio is introduced into the processing chamber 22 via the gas introduction pipe 23. A circular exhaust port 25 is disposed on the lower portion of the processing chamber 22 and below the top surface of the sample stage 101 and the process gas 24 introduced into the processing chamber 22 or reaction products generated by etching are exhausted to the outside of the processing chamber 22 via the exhaust port 25 by an operation of the exhaust device communicating with the exhaust port 25 and disposed below the vacuum vessel 35.

A pressure adjustment valve 26 including a plurality of plate-like flaps configured to rotate around a shaft disposed in a transverse direction of an axis of a pipe connecting an inlet of the turbo-molecular pump 27 configuring the exhaust device and the exhaust port 25 and variably adjust the magnitude of a flow channel cross-section of the pipe according to a position of a rotation angle is disposed on the pipe. A flow amount or a speed of exhaust from the exhaust port 25 is adjusted by adjusting an opening of the flow channel by rotation of the plurality of flaps of the pressure adjustment valve 26. By a balance of a flow amount or a speed of the process gas 24 from an opening of the gas introduction pipe 23 at the side of the processing chamber 22 and the flow amount or the speed of the exhaust from the exhaust port 25, an internal pressure of the processing chamber 22 is adjusted to a value suitable for a process or an operation of the plasma processing device in a range of about several Pa to tens of Pa.

A coil 28 wound along an outer wall of the rid member 21 is disposed on the rid member 21 configuring an upper portion of the vacuum vessel 35 on the processing chamber 22. One end side of the coil 28 is electrically connected to a power supply 30 for plasma generation to be a power supply outputting high-frequency power and the high-frequency power of a predetermined frequency, for example, 13.56 MHz is supplied from the power supply 30 for the plasma generation to the coil 28.

Atoms or molecules of the process gas 24 in the processing chamber 22 are excited by the electric field generated by the induction magnetic field formed around the coil 28 through which a current of the high-frequency power flows and the plasma 29 of the induction-coupled type is generated in a space of the processing chamber 22 on the sample stage 101. The wafer W on the sample stage 101 faces the plasma 29, charged particles of the plasma 29 are attracted to a film layer of a process target on a top surface of the wafer W by a bias potential formed on the wafer W by high-frequency power of a predetermined frequency supplied from a different high-frequency power supply not illustrated in the drawings to a metallic electrode disposed in the sample stage 101 and are caused to collide with the film layer, and an etching process is executed. If completion of the etching process is detected by a detector not illustrated in the drawings, supply of the high-frequency power to the coil 28 is stopped, the plasma is extinguished, supply of the high-frequency power for the bias formation is stopped, and etching is stopped. Then, the wafer W is carried out from the processing chamber 22, predetermined gas is introduced into the processing chamber 22, the plasma is formed, and plasma cleaning to remove attachments attached to an inner wall of the processing chamber 22 or cause a surface of the inner wall to become a state suitable for starting processing is performed.

In addition, the sample stage 101 is connected to an upper end of a movable shaft 31 having a circular cylindrical shape of which a lower portion is configured to be movable in a vertical direction and is supported to the movable shaft 31 and the sample stage 101 is configured to be movable in the vertical direction according to a movement of the vertical direction of the movable shaft 31, even when an inner portion of the processing chamber 22 is in a vacuum state. The sample stage 101 is moved in the vertical direction and a distance between the wafer W and the plasma 29 is adjusted to a desired distance, so that etching performance is adjusted.

To control a temperature of the wafer W, a cooling medium flow channel through which a cooling medium circulates is disposed in a metallic member of the sample stage 101. The cooling medium of which a temperature is adjusted to a predetermined temperature by a temperature adjustment unit 33 connected to the cooling medium flow channel via a pipe is supplied to the cooling medium flow channel and circulates. Then, the cooling medium returns to the temperature adjustment unit 33 and circulates. In addition, a space 34 between a back surface of the sample stage 101 and a bottom surface of the processing chamber 22 of the vacuum vessel 35 is also decompressed to a predetermined vacuum degree by exhaust from the exhaust port 25.

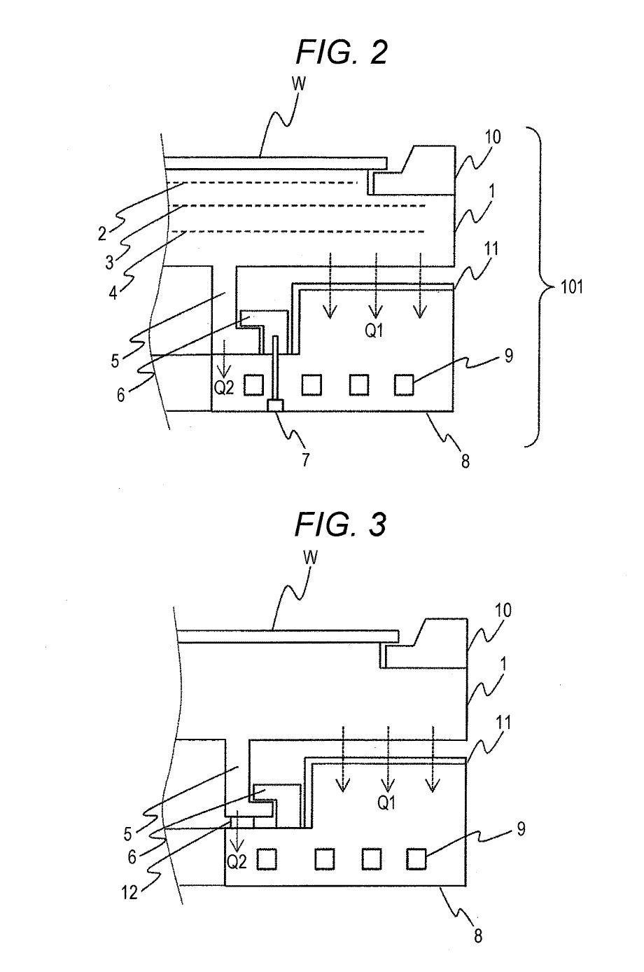

A configuration of the sample stage 101 according to this embodiment will be described using FIG. 2. FIG. 2 is a longitudinal cross-sectional view schematically illustrating a configuration of the sample stage according to the embodiment illustrated in FIG. 1. In FIG. 2, a cross-section for a surface of a longitudinal direction including any radial direction from a center axis of the sample stage 101 having a circular cylindrical shape is illustrated.

The sample stage 101 according to this embodiment includes a dielectric block 1 of a discoid shape or a circular cylindrical shape that disposes a process target sample W (hereinafter, referred to as the wafer W) on a top surface thereof and a metallic cooling jacket 8 of a ring shape that is disposed below the dielectric block 1 and has an external shape of a circular cylindrical shape or a discoid shape and in which a feeding line and a coaxial cable to supply power to an electrode disposed in the dielectric block 1 on the metallic cooling jacket 8 or a through-hole where a pipe to supply heat transfer gas to an introduction port for the heat transfer gas in a top surface is disposed is disposed in a center portion. The dielectric block 1 is configured using a sintered compact obtained by forming a ceramic material in a predetermined shape and sintering the ceramic material.

A metallic electrostatic adsorption electrode 2, a high-frequency electrode 3, and a heat generation layer 4 having a film shape are disposed in the dielectric block 1. The electrostatic adsorption electrode 2 is electrically connected to a direct-current power supply not illustrated in the drawings forms a charge between the electrostatic adsorption electrode 2 and the wafer W with a dielectric material therebetween, by a voltage supplied from the direct-current power supply, generates electrostatic force, adsorbs the wafer W on a top surface of the dielectric block 1, and holds the wafer W on the top surface of the dielectric block 1.

A cylindrical support member 5 made of a dielectric material and having a circular cylindrical shape or a cylindrical shape is disposed below a bottom surface of the dielectric block 1. In this embodiment, the cylindrical support member 5 is formed as a part of the dielectric block 1 and is sintered. However, the cylindrical support member 5 may be formed as a different member and may be connected to the dielectric block 1.

As the dielectric used as a material configuring the dielectric block 1 and the cylindrical support member 5, ceramic is used from the viewpoint of heat resistance and corrosion resistance. Particularly, because the dielectric block 1 according to this embodiment functions as an electrostatic chuck to electrostatically adsorb the wafer W, a material of the dielectric block 1 is appropriately selected from materials such as pure alumina ceramic, ceramic obtained by adding titanium oxide to alumina, and aluminum nitride to obtain desired chuck performance.

The cylindrical support member 5 according to this embodiment is divided into portions of two steps in a vertical direction with a stepped circular cylinder and has a shape in which an outer diameter of a lower portion thereof is larger than an outer diameter of an upper portion. In this example, a large-diameter portion of the lower portion is a portion of a flange shape that has the diameter larger than the diameter of the upper portion, including a lower end. A top surface of the lower portion contacts a bottom surface of a fixing member 6. Thereby, the lower portion is pushed downward and a position thereof is fixed to the cooling jacket 8.

The fixing member 6 has an external shape of a shape of a discoid or a circular cylinder having an external diameter larger than the diameter of the large-diameter portion of the lower portion of the cylindrical support member 5 and includes a recessed portion into which the lower portion of the flange shape is inserted and fitted. The flange-shaped portion of the lower portion of the cylindrical support member 5 is inserted into the recessed portion, a top surface of the flange-shaped portion and a bottom surface of the recessed portion contact each other, and the flange-shaped portion and the recessed portion are connected to each other. The fixing member 6 and the cooling jacket 8 are fastened by a fixing bolt 7 inserted through the through-hole from a lower portion of the cooling jacket 8 and the dielectric block 1 and the cylindrical support member 5 are held by the fixing member 6 and are fixed on the cooling jacket 8 together with the fixing member 6.

A plurality of members disposed to surround the fixing member 6 at outer circumference thereof in a state in which the fixing member 6 is connected to the lower portion of the cylindrical support member 5 are coupled, for example, a plurality of members having shapes of circular arcs are connected at ends of the circular arcs thereof and as a result, the fixing member 6 has a ring shape. In the case in which the cylindrical support member 5 is made of ceramic, if a bolt hole is formed by processing a portion of a material of ceramic of the cylindrical support member 5 directly, strength is insufficient and damages such as cracking and chipping or dusts may occur. For this reason, the cylindrical support member 5 is fixed on the cooling jacket 8 using the fixing member 6 and the fixing bolt 7 made of a metal or a resin.

As described above, a cooling medium flow channel 9 is disposed in the metallic cooling jacket 8 having conductivity, the temperature adjusted cooling medium is supplied to the cooling medium flow channel 9, and the cooling medium circulates, so that the temperature of the cooling jacket 8 is adjusted. When heat generated by causing ions to be incident on the wafer W or supplying a direct current to the heat generation layer 4 disposed below the high-frequency electrode 3 is supplied to the dielectric block 1, heat of a heat transfer amount Q1 is transferred between the bottom surface of the ring shape of the dielectric block 1 and the top surface of the ring shape of the cooling jacket 8, heat of a heat transfer amount Q2 is transferred between the bottom surface of the lower portion of the cylindrical support member 5 and the bottom surface of the recessed portion disposed on the center side of the top surface of the ring shape of the cooling jacket 8 into which the cylindrical support member 5 and the fixing member 6 are inserted, and the heat is exhausted from the dielectric block 1 to the cooling jacket 8.

When a gap between the dielectric block 1 and the cooling jacket 8 communicates with the processing chamber 22 around the sample stage 101 and is in the same vacuum state, the heat of Q1 is mainly transferred by radiation. In this embodiment, outer diameters of the heat generation layer 4 disposed in a region of a circular shape or a shape of a plurality of circular arcs in the dielectric block 1 and the cooling jacket 8 are larger than an outer diameter of the wafer W.

That is, a susceptor ring 10 configured using silicon, alumina, or quartz is disposed in a region of an outer circumferential side of the placement surface on which the wafer W on the top surface of the dielectric block 1 is disposed. The heat generation layer 4 is disposed below a center portion of the dielectric block 1 and an outer circumferential end thereof is disposed below the susceptor ring 10. An insulating layer 11 is disposed between the bottom surface of the dielectric block 1 of the outer circumferential side of the cylindrical support member 5 and the top surface of the cooling jacket 8. The insulating layer 11 will be described in detail in a second embodiment.

In the related art that has a cooling medium flow channel disposed in a metallic block configuring a sample stage, a heater disposed on the cooling medium flow channel, and an electrostatic chuck disposed on a top surface of the metallic block, if large power is supplied to the heater to increase the temperature of the wafer, thermal expansion occurs in the vicinity of a heater portion in the metallic block and the entire metallic block is transformed into a convex portion. The placement surface on which the wafer on the metallic block is disposed is also transformed into a convex portion and adsorption is disabled in a region of the outer circumferential side of the wafer. Meanwhile, like the configuration according to this embodiment, the dielectric block 1 and the cooling jacket 8 are connected by the cylindrical support member 5 disposed in the center portion and are fixed and both surfaces face with a gap therebetween in the region of the outer circumferential side, so that restricts of the dielectric block 1 and the cooling jacket 8 do not exist essentially or decrease in an outer circumferential portion of the radial direction of the sample stage or the dielectric block 1 in which a thermal expansion amount increases, and the transformation of the dielectric block 1 is suppressed. Therefore, when it is necessary to increase the temperatures of the upper and lower portions of the sample stage 101 to realize the temperatures suitable for processing the wafer W, such as increasing the temperature of the cooling jacket 8 to 20° C. and increasing the temperature of the dielectric block 1 to 200° C. or more, the wafer W can be adsorbed on the top surface of the dielectric block 1 without deteriorating the electrostatic adsorption with respect to the radial direction.

In addition, a variation of the radial direction of the heat transfer amount from the dielectric block 1 to the cooling jacket 8 can be reduced by the heat transfer amount Q1 between the back surface of the outer circumferential side of the dielectric block 1 and the top surface of the outer circumferential side of the cooling jacket 8 and the heat transfer amount Q2 between the lower portion of the cylindrical support member 5 and the top surface of the center portion of the cooling jacket 8. For example, when the heat transfer amount of the sample stage 101 is only Q1 in the region of the outer circumferential side, the heat is transferred from the region of the outer circumferential side of the wafer W to the cooling jacket 8. However, heat exhaust is relatively small in the region of the center side of the wafer W and the temperature increases in the vicinity of the center of the wafer W. As in this embodiment, the heat of the amount of Q2 is transferred from the cylindrical support member 5 supporting the dielectric block 1 at the center portion from the dielectric block 1, so that the temperature of the center portion of the wafer W is suppressed from increasing.

The magnitudes of the heat transfer amounts Q1 and Q2 are appropriately selected in consideration of a distance of the gap between the back surface of the outer circumferential side of the dielectric block 1 and the top surface of the outer circumferential side of the cooling jacket 8, facing area, and a contact area of the large-diameter portion of the bottom portion of the cylindrical support member 5 and the bottom surface of the recessed portion of the center portion of the cooling jacket 8, so that a value of a predetermined temperature of the wafer W and a distribution thereof can be realized. In the present invention, the outer circumferential edge of the heat generation layer 4 or the cooling jacket 8 is disposed to be closer to the outside than the outer diameter of the wafer W, so that non-uniformity of the temperature occurring in the outer circumferential portions of the heat generation layer 4 and the cooling jacket 8 is suppressed, and a bad influence on the value of the temperature of the wafer W and the distribution thereof is reduced.

The discoid or circular cylindrical outer diameters of the dielectric block 1 and the cooling jacket 8 have the same dimensions. In addition, as illustrated in FIG. 1, an outer circumference protection member 32 made of a dielectric having relatively high plasma resistance, such as alumina and quartz, is disposed to surround the sample stage 101 at the portion of the outer circumferential side of the sample stage 101, a lateral surface of the sample stage 101 is separated from the processing chamber 22, and a situation where the plasma 29 is supplied and the lateral surface is deformed by a mutual action with the plasma or attachments are deposited is suppressed from occurring. In this case, the outer diameter of the heat generation layer 4 buried into the dielectric block 1 becomes smaller than the outer diameter of the cooling jacket 8. However, the heat generation layer 4 needs to be disposed such that the outer diameter thereof is larger than at least the outer diameter of the wafer W.

For example, when the diameters of the heat generation layer 4 and the wafer W are equal as φ300 mm and the outer diameter of the cooling jacket is large as φ400 mm, the temperature of the wafer W decreases in the outer circumferential portion and in-plane temperature uniformity is not obtained. For this reason, the heat generation layer 4 and the cooling jacket 8 having the outer diameters larger than the outer diameter of the wafer W are disposed, so that the temperature of the outer circumferential portion of the wafer W can be suppressed from decreasing, and the in-plane temperature of the wafer can be maintained constantly.

The movable shaft 31 is only connected to the bottom surface of the cooling jacket 8 and is not connected to the dielectric block 1. For this reason, the magnitude of the gap between the dielectric block 1 and the cooling jacket 8 is constant even if the movable shaft 31 moves in a vertical direction. Therefore, even in the case in which the sample stage 101 is moved vertically by driving the movable shaft 31 in the middle of the etching process and the distance between the wafer W and the plasma 29 is adjusted, if the discharge in the gap is suppressed at any point of time during the process, the discharge in the gap is suppressed even in the following process. Meanwhile, in the case in which only the dielectric block 1 can move in a vertical direction and the position of the cooling jacket 8 is fixed, if the dielectric block 1 moves, the magnitude of the gap between the dielectric block 1 and the cooling jacket 8 changes. As a result, the discharge may occur in the gap by the electric field formed by supplying the high-frequency power to the high-frequency electrode 3.

In addition, in this embodiment, the electric field formed in the processing chamber 22 by the high-frequency power supplied from the high-frequency power supply 16 to the coil 28 is blocked by the conductive cooling jacket 8. Therefore, even though the sample stage 101 moves in a vertical direction and the magnitude of the gap (the magnitude of a space) changes, the discharge in the space 34 below the cooling jacket 8 is suppressed.

A detailed configuration of the gap between the dielectric block 1 and the cooling jacket 8 of the sample stage according to this embodiment will be described using FIG. 3. FIG. 3 is a longitudinal cross-sectional view schematically illustrating a configuration of the sample stage according to the embodiment illustrated in FIG. 2. In FIG. 3, components denoted with the same reference numerals as those in FIGS. 1 and 2 are not described.

The lower portion of the cylindrical support member 5 of the dielectric block 1 according to this embodiment has a shape in which the outer diameter thereof is larger than the outer diameter of the circular cylindrical portion of the upper portion. The large-diameter portion of the lower portion is fitted into the recessed portion of the center side of the fixing member 6 disposed at the outer circumferential side thereof, contacting the top surface of the large diameter portion, and pushed downward and is held and the large-diameter portion is fixed on the conductive cooling jacket 8 by the fixing bolt 7. When the dielectric block 1 is disposed on the cooling jacket 8, first, the fixing member 6 is mounted on the cylindrical support member 5, the cylindrical support member 5 is inserted into a recessed portion of a center portion of the cooling jacket 8 and is disposed on a top surface of a bottom portion thereof, the fixing bolt 7 is inserted into the through-hole from the bottom surface of the cooling jacket 8, the fixing member 6 and the cooling jacket 8 are fastened, and positions of the cylindrical support member 5 and the dielectric block 1 connected to the upper portion of the cylindrical support member 5 are fixed on the cooling jacket 8.

The fixing member 6 according to this embodiment is a member in which ends of a plurality of annular members (in this embodiment, two annular members) of semicircular shapes are connected and one ring shape is configured and is a ring-shaped member disposed to cover the cylindrical support member 5 at the outer circumferential side of the cylindrical support member 5 in a state in which the fixing member 6 is disposed on and fixed on the flange portion of the lower portion of the cylindrical support member 5. In state in which the fixing member 6 is disposed outside the cylindrical support member 5 to surround the outer circumference of the large-diameter portion of the lower portion of the cylindrical support member 5 and is fastened to the cooling jacket 8, a gap having a shape of a ring of the length L2 with respect to a horizontal direction exists between a sidewall of the outer circumferential side of the upper portion of the cylindrical support member 5 and an inner wall of the recessed portion of the circular cylindrical shape of the cooling jacket 8.

The length L2 is determined by dimensions such as the outer diameter of the cylindrical support member 5, the inner and outer diameters of the fixing member 6, and the radius of the recessed portion. Meanwhile, the magnitude —L1 of a gap between the bottom surface of the dielectric block 1 of the outer circumferential side of the cylindrical support member 5 and the top surface of the outer circumferential side of the recessed portion of the cooling jacket 8 is determined by the length of the cylindrical support member 5 and the depth of the recessed portion of the center portion of the cooling jacket 8. To maximize heat transfer performance between both sides, the magnitude L1 of the gap is preferably minimized.

In this embodiment, L1 is several mm, preferably, 1 mm or less and L2 depends on the dimension of the fixing member 6 into which the fixing bolt 7 is inserted. If mechanical strength at the time of fastening using the fixing bolt 7 is considered, the magnitudes of the gaps are in a relation of L2>L1.

In this state, in the case in which the high-frequency power for the bias potential formation is supplied from the high-frequency power supply 16 for the bias potential formation to the high-frequency electrode 3 disposed in the dielectric block 1, because L2 is relatively large, the possibility that the discharge occurs in a direction of B in the drawings becomes high as compared with L1. A voltage where the discharge in the gap starts is associated with the magnitude of the gap and a discharge start voltage becomes low in the direction of B rather than a direction of A.

In the case of etching a nonvolatile material, because the material has low chemical reactivity, a sputtering effect by ion energy becomes a main etching reaction and it is preferable to increase incidence energy of ions, from the viewpoint of improving verticalization of a processing shape or the throughput. For this reason, it is anticipated that it is necessary to increase an output voltage of the high-frequency power supply 16. Meanwhile, in this embodiment, the cooling jacket 8 includes a configuration in which the cooling jacket is electrically connected to a ground or a ground electrode and has a ground potential. For this reason, a potential gradient is generated between the high-frequency electrode 3 and the cooling jacket 8 and the possibility that the discharge occurs in the gap between the dielectric block 1 and the cooling jacket 8 becomes high.

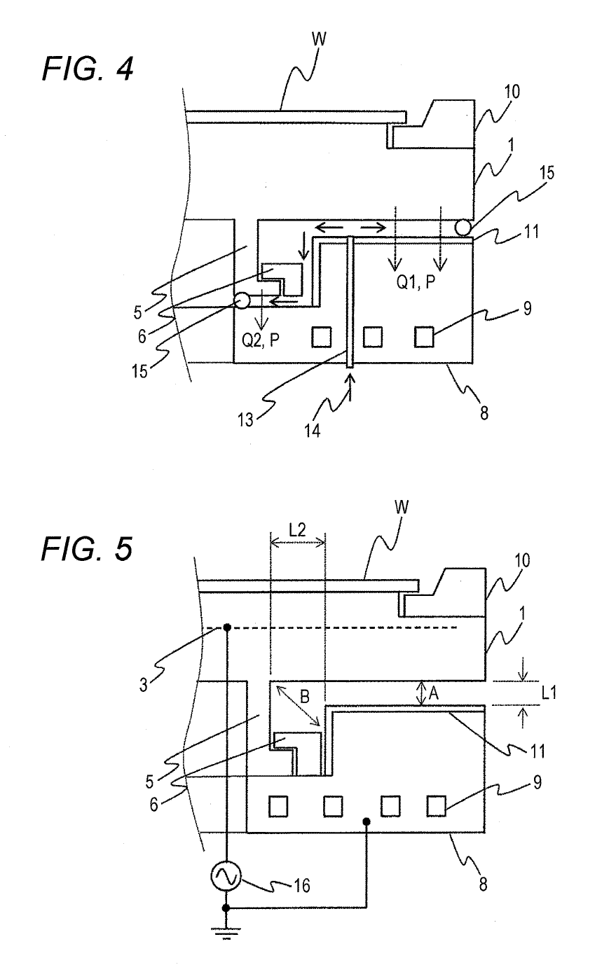

FIG. 4 is a graph schematically illustrating a characteristic of discharge in the plasma processing device according to the embodiment illustrated in FIG. 1. The characteristic is generally known as a Paschen's law. FIG. 4 illustrates that a discharge start voltage of a space is associated with a pressure P and an inter-electrode distance d and the association is applicable to both direct current discharge and high frequency discharge.

In the direction of A illustrated in FIG. 3, because the vertical direction gap magnitude L1 is small, a P·d value also decreases and the discharge start voltage increases. Meanwhile, in the direction of B illustrated in FIG. 3, because the horizontal direction gap magnitude L2 is large, a P·d value also increases and the discharge start voltage decreases. In this embodiment, the discharge is generated relatively easily in the direction of B. The discharge in the sample stage 101 generated during processing of the wafer W causes the bias potential or the plasma potential to become unstable, exerts a bad influence on processing of the wafer W, and lowers a yield of the processing.

In the sample stage 101 according to this embodiment, to suppress the internal discharge, the insulating layer 11 is disposed on the top surface of the cooling jacket 8 as illustrated in FIGS. 2 and 3. The top surface of the cooling jacket 8 and the inner wall surface of the recessed portion are covered with the insulating layer 11, a voltage applied to the gap between the dielectric block 1 and the cooling jacket 8 is distributed to the insulating layer 11, the voltage decreases, and the discharge in the gap, particularly, the discharge in the direction of B is suppressed.

In addition, the cooling jacket 8 may use a metallic material such as alumina, from the viewpoint of conductivity and thermal conductivity. However, if the cooling jacket 8 is exposed to the discharge in a state in which a metal is exposed, this causes a foreign material or a contaminated material. If the insulating layer 11 is disposed, a production amount of the foreign material or the contaminated material can be decreased greatly as compared with the metallic material, even though the discharge occurs in the gap.

The insulating layer 11 may be formed by sintering or mechanical processing using ceramic or resin. When aluminum is used in the cooling jacket, anodizing may be executed on an aluminum surface and an anode oxide film may be used as the insulating layer 11. In addition, alumina frame spraying processing and insulating resin coating may be formed on the surface of the cooling jacket 8 to form the insulating layer 11.

A modification of the embodiment will be described using FIG. 5. FIG. 5 is a longitudinal cross-sectional view schematically illustrating a configuration of a sample stage of a plasma processing device according to a modification of the embodiment illustrated in FIG. 1. In FIG. 5, components denoted with the same reference numerals as those in FIGS. 1 to 3 are not described.

In FIG. 5, a heat insulating material 12 is interposed between the bottom surface of the large-diameter portion of the lower portion of the cylindrical support member 5 of the dielectric block 1 and the bottom surface of the recessed portion of the center portion of the cooling jacket 8 into which the cylindrical support member 5 is inserted and the cylindrical support member 5 and the cooling jacket 8 contact each other. The heat transfer amount Q2 between the cylindrical support member 5 and the cooling jacket 8 is reduced by the heat insulating material 12. The length of the axial direction of the cylindrical support member 5 is preferably small to miniaturize the device. However, the length of the cylindrical support member 5 is preferably large from the viewpoint of heat insulation.

The heat transfer amount Q2 may become large excessively and the temperature of the wafer W may become lower than a temperature in an allowed range in the region of the center portion, according to selection of a process condition or a dimension of the sample stage 101. In this case, the heat insulating material 12 having a dimension such as a thickness selected previously is interposed between the bottom surface of the cylindrical support member 5 and the bottom surface of the recessed portion of the cooling jacket 8 and the heat transfer amount Q2 is adjusted.

By this configuration, both the miniaturization of the device and the desired heat transfer amount Q2 can be realized. As the heat insulating material 12, a material having a low heat transfer rate may be selected. For example, a metallic material such as stainless and titanium or a resin material can be used.

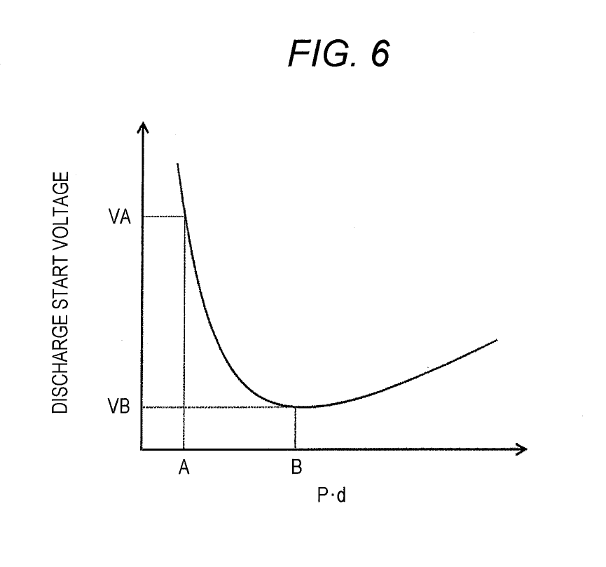

Another modification will be described using FIG. 6. FIG. 6 is a longitudinal cross-sectional view schematically illustrating a configuration of a sample stage of a plasma processing device according to another modification of the embodiment illustrated in FIG. 1. In FIG. 6, components denoted with the same reference numerals as those in FIGS. 1 to 5 are not described.

In this example, a sealing member 15 such as an O-ring is disposed in a gap between the dielectric block 1 and the cylindrical support member 5 and the cooling jacket 8 to airtightly separate the gap from an internal space of the processing chamber 22 around the sample stage 101 and heat transfer gas 14 such as He is supplied to a space in the gap airtightly separated from a surrounding portion. The heat transfer gas 14 is supplied from a storage unit of the heat transfer gas 14 to the gap via a through-hole provided in the cooling jacket 8 or a gas line 13 composed of a pipe, from the lower portion of the sample stage 101. As the heat transfer gas 14, rare gas other than He may be used.

In this modification, He supplied to the gap is distributed to the gap between the dielectric block 1 of the outer circumferential side of the cylindrical support member 5 and the cooling jacket 8 and the gap between the inner wall and the bottom surface of the recessed portion disposed in the center portion of the cooling jacket 8 and the cylindrical support member 5 and are filled into the gaps. A supply amount of the heat transfer gas or an internal pressure of the gap is adjusted, so that the heat transfer amounts Q1 and Q2 increase or decrease. As a result, a level of an entire heat transfer amount between the dielectric block 1 and the cooling jacket 8 can be variably adjusted while a balance of the heat transfer amounts Q1 and Q2 by the dimensions of the cylindrical support member 5 and the dielectric block 1 with respect to an in-plane direction of the top surface of the dielectric block 1 or the wafer W is maintained.

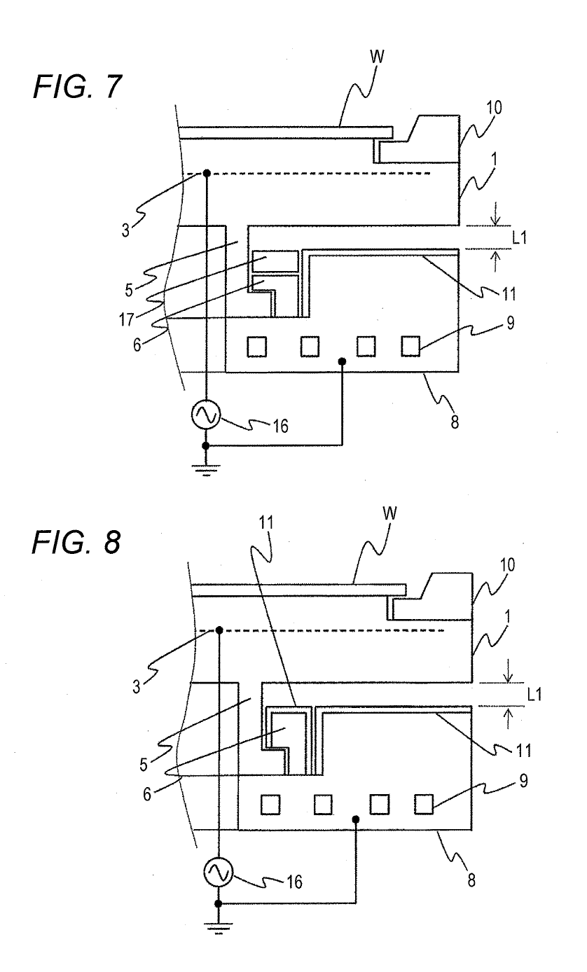

Next, another modification of the embodiment will be described using FIGS. 7 and 8. FIGS. 7 and 8 are longitudinal cross-sectional views schematically illustrating a configuration of a sample stage of a plasma processing device according to another modification of the embodiment illustrated in FIG. 1. In FIGS. 7 and 8, components denoted with the same reference numerals as those in FIGS. 1 to 6 are not described.

As described above, in this embodiment, in the direction of B illustrated in FIG. 3, because the magnitude L2 of the gap of the horizontal direction is relatively larger than the magnitude L1, a P·d value also increases and the discharge start voltage decreases. In this modification, a second insulating material 17 is disposed on the fixing member 6 to suppress the discharge of the direction of B in the gap of L2. By providing the second insulating material 17, at least a part of the gap is buried into an insulating material, a voltage is distributed to the insulating material of the second insulating material 17, a voltage between the surfaces in the gap is reduced, and the discharge is suppressed.

Similar to the fixing member 6, the second insulating material 17 according to this example is a ring-shaped member that is configured by, for example, connecting ends of two annular members of semicircular or arc-like shapes and is a ring-shaped member disposed to surround the outer circumferential sidewall of the cylindrical support member 5 in a state in which the second insulating material 17 is mounted on the cylindrical support member 5 together with the fixing member 6. Before connecting the cylindrical support member 5 including the large-diameter portion of the lower portion having the diameter larger than the diameter of the upper portion to the cooling jacket 8, the second insulating material 17 and the fixing member 6 are mounted on the cylindrical support member 5, the cylindrical support member 5 and the second insulating material 17 and the fixing member 6 mounted on the cylindrical support member 5 are inserted into the recessed portion disposed in the center portion of the cooling jacket 8, the bottom surfaces thereof contact each other, and these components are connected, fastened, and fixed.

In the example illustrated in FIG. 8, the magnitude of the gap of the direction of B of FIG. 3 is reduced by burying the gap of L2 by disposing the second insulating material 17 around the upper portion of the cylindrical support member 5 and the magnitude of the gap of the direction of B is reduced by burying the gap of L2 into the fixing member 6. When a metallic material is used in the fixing member 6, the insulating layer 11 can be disposed on the surface, similar to the top surface of the cooling jacket 8 of the outer circumferential side of the fixing member 6.

According to the embodiment and the modifications described above, the heat transfer amount between the dielectric block 1 and the cooling jacket 8 with respect to the radial direction of the sample stage 101 having the circular cylindrical shape is adjusted to a value in a desired range suitable for processing the wafer W, so that the variation of the temperature of the top surface of the sample stage 101 or the wafer W can be reduced. Or, the heat transfer amount between the dielectric block 1 and the cooling jacket 8 with respect to the radial direction is realized with a desired amount or a distribution thereof, so that the temperature of the top surface of the wafer W or the sample stage 101 and a distribution thereof can be adjusted in a predetermined range, and a yield of processing of the wafer W can be improved.

In the embodiment and the modifications described above, the plasma processing device of the induction-coupled type has been described. However, even in a device using known technology such as microwave ECR and a capacitance-coupled type as a method of generating plasma, the same effects as the effects according to the present invention can be achieved.

In addition, the same effects can be achieved by applying the invention to other devices in which it is necessary to manage the wafer temperature, such as an ashing device, a sputter device, an ion implantation device, a resist coater, a plasma CVD device, a flat panel display manufacturing device, and a solar battery manufacturing device, in addition to the plasma processing device executing the etching process on the wafer W.

What is claimed is:

1. A plasma processing device comprising:
a processing chamber which is disposed in a vacuum vessel and is compressed;
a sample stage which is disposed in the processing chamber and on which a wafer of a process target is disposed and held; and
a mechanism for forming plasma in the processing chamber on the sample stage, wherein
the sample stage includes a block which is made of a dielectric and has a discoid shape, a jacket which is disposed below the block with a gap therebetween, is made of a metal, and has a discoid shape, a recessed portion which is disposed in a center portion of a top surface of the jacket and into which a cylindrical member disposed below a center portion of the block and made of a dielectric is inserted, and a cooling medium flow channel which is disposed in the jacket and through which a cooling medium circulates; and
the block and the jacket transfer heat through a gap between the cylindrical member and a bottom surface of the block of an outer circumferential side thereof.

2. The plasma processing device according to claim 1, wherein:
the cylindrical member has a lower portion having a diameter larger than a diameter of an upper portion and the block and the jacket transfer heat through a gap between the lower portion and the recessed portion.

3. The plasma processing device according to claim 2, further comprising:
a ring-shaped member which is a metallic ring-shaped member disposed in the recessed portion and surrounding outer circumference or a top surface of the lower portion of the cylindrical member having a large diameter and is fastened to the jacket and holds the cylindrical member on the jacket.

4. The plasma processing device according to claim 3, wherein:
an insulating member which is disposed to surround the cylindrical member in the recessed portion on a top surface of the metallic ring-shaped member.

5. The plasma processing device according to claim 1, wherein:
heat transfer gas is supplied to a gap between the block and the jacket.

6. The plasma processing device according to claim 5, wherein:
the plasma processing device has a function of variably adjusting a pressure of the heat transfer gas in the gap.

7. The plasma processing device according to claim 1, wherein:
a diameter of each of a heat generation layer disposed in a circular arc shape or a discoid shape in the block and the jacket is larger than a diameter of the wafer.
